(19) United States
(12) Patent Application Publication
(10) Pub. No.: US 2018/0007808 A1
(43) Pub. Date: Jan. 4, 2018

(54) INFORMATION PROCESSING APPARATUS, METHOD FOR MANAGING, NON-TRANSITORY COMPUTER-READABLE RECORDING MEDIUM HAVING STORED THEREIN MANAGEMENT PROGRAM, AND METHOD FOR SPECIFYING INSTALLING POSITION OF ELECTRONIC DEVICE

(71) Applicant: FUJITSU LIMITED, Kawasaki-shi (JP)

(72) Inventor: Yoshinobu MIZUTANI, Kita (JP)

(73) Assignee: FUJITSU LIMITED, Kawasaki-shi (JP)

(21) Appl. No.: 15/606,151

(22) Filed: May 26, 2017

(30) Foreign Application Priority Data
Jun. 30, 2016 (JP) 2016-130351

(51) Int. Cl. H05K 7/14; G01R 19/04

(52) U.S. Cl. CPC H05K 7/1498; G01R 19/04; H05K 7/1492

(57) ABSTRACT

An information processing apparatus includes an applier that applies an alternating voltage to a lead provided for a frame of a rack that stores one or more electronic devices along a direction of arrangement of the electronic devices, the lead being in contact with a fixing part when the electronic devices are installed; a measure that measures an alternating wave of the alternating voltage flowing through the lead; and a specifier that specifies an installing position of an electronic device by referring to reference waveform information with a waveform of the measure alternating wave, the reference waveform information associating an installing state of the electronic device in the rack with a waveform pattern of the alternating wave measured under the installing state. This configuration reduces steps needed for managing a token, an archive, a token password and enhances the security level of the terminal device.

### CROSS-REFERENCE TO RELATED APPLICATION

This application is based upon and claims the benefit of priority of the prior Japanese Patent application No. 2016-130351, filed on Jun. 30, 2016, the entire contents of which are incorporated herein by reference.

### FIELD

The embodiment discussed herein is directed to an information processing apparatus, a method for managing, a non-transitory computer-readable recording medium having stored therein a management program, and a method for specifying an installing position of an electronic device.

### BACKGROUND

In managing one or more electronic devices, such as server computers, storage devices, and network devices, being installed in a rack, device information of each electronic device and an installing position information of each electronic device in the rack have been generally managed.

The device information includes information representing the model name and the serial number of an electronic device, and parts mounted thereon. The device information is obtained from an electronic device being accessed by accessing the electronic device via a network, for example, assigning the IP address of the electronic device.

The installing position information is information representing a position where an electronic device is installed. The installing position information is obtained by referring to the position information that the operator recorded in a ledger when the electronic device was installed and is registered by human operation.

The operator installs electronic devices in a computer system disposed in, for example, a server room with reference to a job instruction that describes which electronic device will be installed in which position of which rack. After the installation by the operator is completed, the position information representing the installing positions of the electronic devices is reflected in the ledger.

[Patent Literature 1] Japanese Laid-open Patent Publication No. 2007-226582

In the above traditional management of electronic devices, the result of the installation is reflected in the ledger on the basis of the report from the operator. Accordingly, the management information is sometimes not completed until the practical operation is started. The position information are of low preference in the management, but needs to be grasped for the maintenance.

However, the installing position information is collected and managed by human operation as the above. Increase in the number of electronic device increases complex load of registering and managing the information. Furthermore, in the event of regular updating of a server, the installing position information also needs to be updated, which requires load.

### SUMMARY

According to an aspect of the embodiments, an information processing apparatus includes an applier that applies an alternating voltage to a lead being provided for a frame of a rack that stores one or more electronic devices along a direction of arrangement of the one or more electronic devices, the lead being in contact with a fixing part when the one or more electronic devices are installed; a measure that measures an alternating wave of the alternating voltage flowing through the lead; and a specifier that specifies an installing position of an electronic device by referring to reference waveform information with a waveform of the alternating wave measured by the measure, the reference waveform information associating an installing state of installing the one or more electronic devices in the rack with a waveform pattern of the alternating wave measured under the installing state.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram schematically illustrating the configuration of a computer system according to a first embodiment;

FIG. 2 is a partial perspective view illustrating a method of attaching an electronic device to a rack in a computer system of the first embodiment;

FIG. 3 is a diagram illustrating the configuration of a microstripline in a computer system of the first embodiment;

FIG. 4 is a diagram illustrating an example of the hardware configuration of an installing position detector of a computer system of the first embodiment;

FIG. 5 is a diagram illustrating an alternating wave detected by a voltage detector of a computer system of the first embodiment;

FIG. 6 is a diagram illustrating an alternating wave superimposed in a microstripline of a computer system of the first embodiment;

FIG. 7 is a diagram illustrating an example of a waveform of an alternating wave measured by a voltage detector of a computer system of the first embodiment;

FIG. 8 is a diagram illustrating the functional configuration of an installing position detector of a computer system of the first embodiment;

FIG. 9 is a diagram illustrating an example of waveform pattern information of a computer system of the first embodiment;

FIG. 10 is a diagram illustrating an example of rack specifying pattern information of a computer system of the first embodiment;

FIG. 11 is a diagram illustrating an example of a device management table of a computer system of the first embodiment;

FIG. 12 is a flow diagram illustrating a method of determining a rack type in a computer system of the first embodiment;

FIG. 13 is a flow diagram illustrating a method of determining an installing state of an electronic device in a computer system of the first embodiment;

FIG. 14 is a flow diagram illustrating registration of an electronic device in a rack system of a computer system of the first embodiment;

FIG. 15 is a flow diagram illustrating registration of an electronic device in a rack system of a computer system of the first embodiment; and

FIG. 16 is a flow diagram illustrating registration of an electronic device in a rack system of a computer system of the first embodiment.

### DESCRIPTION OF EMBODIMENT(S)

Hereinafter, an information processing apparatus, a method for managing, a non-transitory computer-readable recording medium having stored therein a management program, and a method for specifying an installing position of an electronic device will now be detailed with reference to accompanying drawings. The following first embodiment is exemplary and has no intention to exclude various modifications and applications of techniques not referred in the first embodiment. In other words, various changes and modifications can be suggested without departing from the scope of the first embodiment (e.g., combining embodiments). The drawings do not illustrate therein all the functions and elements included in the embodiment and may include additional functions and elements to those illustrated in the accompanying drawings.

(A) Configuration:

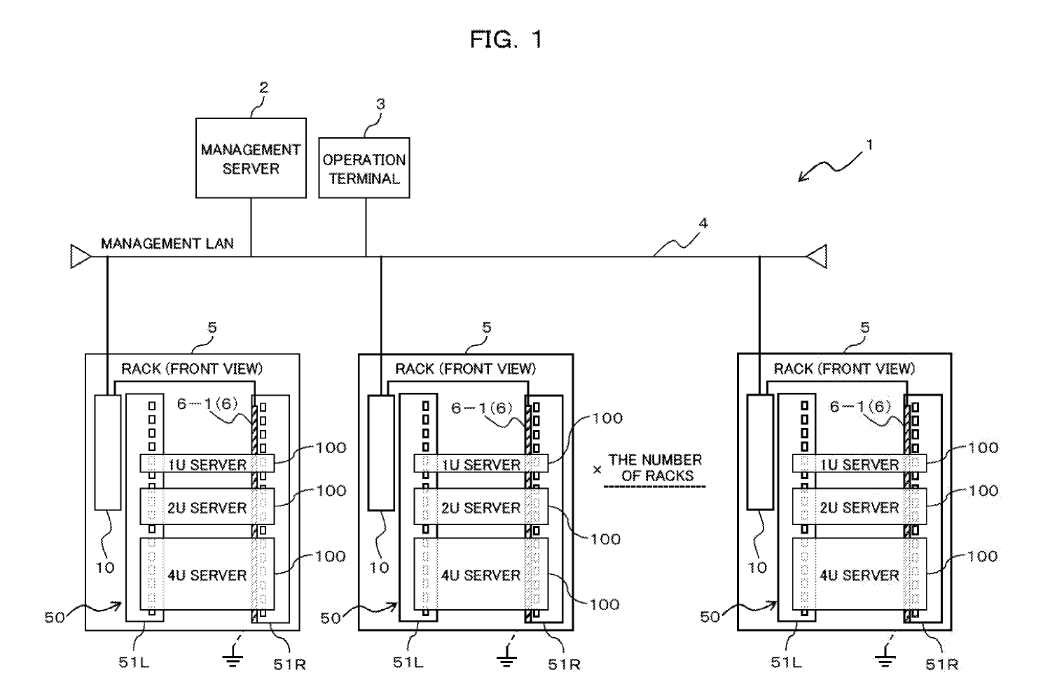

FIG. 1 is a diagram schematically illustrating the configuration of a computer system 1 according to the first embodiment. The computer system (system for managing installing position) 1 illustrated in FIG. 1 includes a management server 2, an operation terminal 3, and multiple rack systems 5. The management server 2, the operation terminal 3, and the rack systems 5 are communicably connected to one another via a network 24.

Each rack system includes a rack 50 and one or more electronic devices 100 installed in the rack 50.

In each rack system 5 of FIG. 1, three electronic devices 100 are vertically arranged in the rack 50.

An electronic device 100 is of rack mounting type (rack installing type), which is used when being installed in the rack 50. In the rack 50, multiple installing areas each in which an electronic device 100 is installed are arranged in, for example, the vertical direction. Installing the electronic devices 100 into the respective installing areas installs any number of electronic devices 100 in the rack 50 in such a posture that the electronic devices 100 are piled.

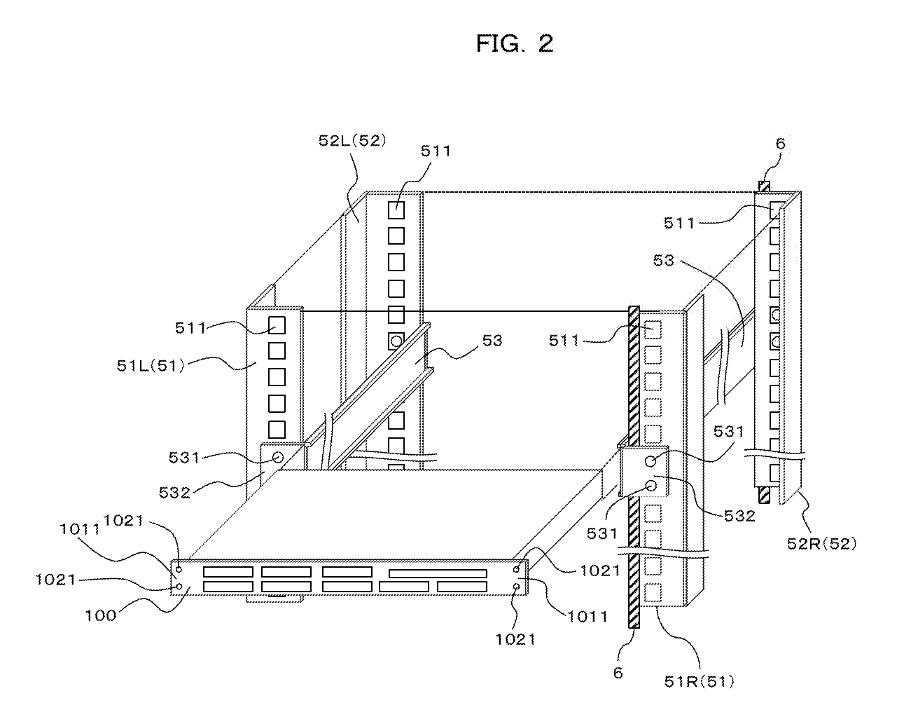

FIG. 2 is a perspective view illustrating a method of attaching an electronic device 50 in a rack 50 in the computer system 1 of the first embodiment.

Each rack 50 includes front mount angle frames 51R and 51L arranged vertically and in parallel with each other and rear mount angle frames 52R and 52L arranged vertically and in parallel with each other.

The front mount angle frames 51R and 51L are vertically arranged in parallel at the front side of the rack 50 while the rear mount angle frames 52R and 52L are vertically arranged in parallel at the rear side of the rack 50.

The front-rear direction in the rack 50 corresponds to a direction of attaching and detaching of an electronic device 100. The direction of arranging the front mount angle frames 51R and 51L is referred to as the forward direction (front side) and the direction of arranging the rear mount angle frames 52R and 52L is referred to as the backward direction (read side). The direction of a horizontal plane perpendicular to the front-rear direction is sometimes referred to as the right-left direction.

Hereinafter, if one of the multiple front mount angle frames needs to be specified, a reference number 51R or 51L is used. An arbitrary front mount angle frame is represented by a reference number 51.

Likewise, if one of the multiple rear mount angle frames needs to be specified, a reference number 52R or 52L is used. An arbitrary rear mount angle frame is represented by a reference number 52.

The front mount angle frame 51R and the rear mount angle frame 52R arranged along the front-rear direction of the rack 50 is connected by a rectangular guide rail 53. Likewise, the front mount angle frame 51L and the rear mount angle frame 52L arranged along the front-rear direction of rack 50 is connected by another rectangular guide rail 53.

The front end and the rear end of each guide rail 53 are folded into L shapes to the right-left direction, so that fixing plates 532 are formed.

One or more fixing holes 531 are provided to each fixing plate 532. In the example of FIG. 2, two fixing holes 531 vertically arranged are formed on each fixing plate 532. In FIG. 2, only the fixing plate 532 on the front side of each guide rail 53 appears, but another fixing plate 532 is formed on the rear side of each guide rail 53.

On the front faces of the front mount angle frames 51R and 51L and the rear faces of the rear mount angle frames 52R and 52L, multiple holes 511 are vertically formed at regular intervals.

The guide rail 53 is fixed to the front mount angle frame 51 by inserting non-illustrated screws into the holes under a state where fixing holes 531 of the fixing plate 532 formed on the front side of the guide rail 53 lay on any two or the holes 511 formed on the front mount angle frame 51 and screwing the overlapping holes with these screws.

Likewise, the guide rail 53 is fixed to the rear mount angle frame 52 by inserting non-illustrated screws into the holes under a state where fixing holes 531 of the fixing plate 532 formed on the rear side of the guide rail 53 lay on any two or the holes 511 formed on the rear mount angle frame 52 and screwing the overlapping holes with these screws.

In each rack 50, the space defined by a pair of guide rails 53 arranged along the horizontal direction (right-left direction) in parallel with each other functions as a slot (installing area) into which an electronic device 100 is placed. The guide rails 53 define the side walls of a slot.

The lower end of each guide rail 53 is folded to an L shape toward the inside of the slot, so that the guide rail 53 can support the electronic device 100 placed in the slot.

The guide rail 53 is formed of a conductive material such as iron or aluminum. However, the material of the guide rail 53 is not limited to a conductive material. Alternatively, the guide rail 53 may be formed of a non-conductive material and the conductivity may be obtained by applying a conductive coating on its surface.

Examples of an electronic device 100 are a disk storage device, a Personal Computer (PC) server, and a switch. An electronic device 100 includes a box-shaped casing and one or more electronic parts for achieving the function thereof. The electronic parts are accommodated in the casing.

The outer size of an electronic device 100 is defined according to a standard. For example, the outer size of the height direction is standardized in a unit called Unit (U). The size of one unit (1U) is 1.75 inch (i.e., 44.45 mm). The electronic devices 100 have heights of multiples of 1U, such as 1U, 2U, 3U, and 4U, according to the types of the electronic devices 100. For example, a server having a size of 1U is sometimes referred to as a 1U server; a server having a size of 2U is sometimes referred to as a 2U server; and a server having a size of 4U is sometimes referred to as a 4U server.

FIG. 1 illustrates an example in which a 1U server, a 2U server, and 4U server are installed each rack system 5.

On the front side of an electronic device 100, a voltage generator 101 is formed which fixes the electronic device 100 to the front mount angle frames 51R and 51L of the rack 50.

The rack fixing part 1011 is a plate part being disposed at the front face of the casing of an electronic device 100 and projecting to the right and left sides along the front face. The rack fixing part 1011 comes into contact with the fixing plates 532 of the guide rails 53 when an electronic device 100 is inserted into the slot of the rack 50. This positions the electronic device 100 with respect to the rack 50.

The rack fixing part 1011 is provided with installing holes 1021 arranged in the longitudinal direction. Under a state where the electronic device 100 is placed in the slot of the rack 50 and the rack fixing part 1011 is in contact with the fixing plates 532 of the guide rails 53, the installing holes 1021 lay on the fixing holes 531 of the guide rails 53 and the holes 511 formed on the front mount angle frames 51R and 51L and screws are inserted into the holes and the electronic device 100 is screwed with the holes 511. This fixes the electronic device 100 to the front mount angle frames 51R and 51L.

This means that guide rails 53 are always fixed to the position where the electronic device 100 is installed in the rack 50.

In the computer system 1, the guide rails 53 are attached only when an electronic device 100 is installed (mounted) in the rack 50. In other words, the computer system 1 is not in a state where only the guide rails 53 are attached but the electronic device 100 is not installed to the attached guide rails 53.

A microstripline 6-1 is pasted onto the front face of the front mount angle frame 51R and a microstripline 6-2 is pasted onto the rear face of the rear mount angle frame 52R both along the vertical direction (i.e., the direction of piling the electronic devices 100).

The microstriplines 6-1 and 6-2 have the same configuration. Hereinafter, if one of the multiple microstriplines needs to be specified, a reference number 6-1 or 6-2 is used. An arbitrary microstripline is represented by a reference number 6.

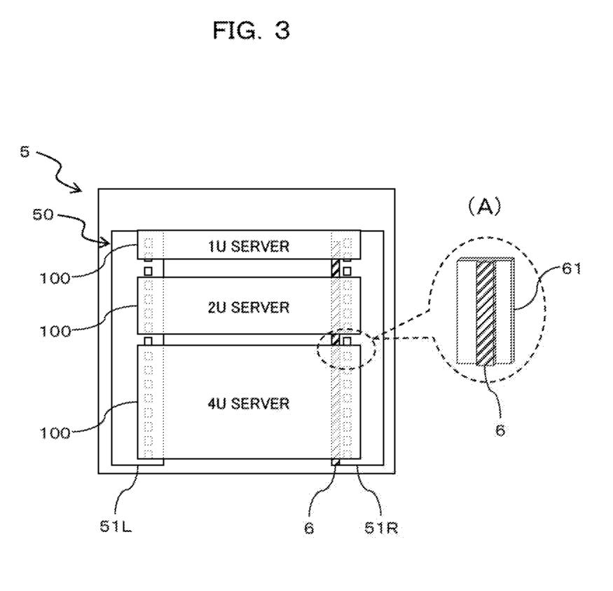

FIG. 3 is a diagram illustrating the configuration of a microstripline 6 in the computer system 1 of the first embodiment.

In FIG. 3, the portion with a reference symbol (A) represents a partial enlargement view of the microstripline 6.

The microstripline 6 is a lead having a uniform impedance (e.g., 50Ω). An example of the microstripline 6 is a copper microstripline having a width of 5 mm and a thickness of 1 mm.

As illustrated in a portion (A) in FIG. 3, the microstriplines 6 are pasted onto the front mount angle frame 51R and the rear mount angle frame 52R via insulator films 61.

This insulates the microstriplines 6 from the front mount angle frame 51R and the rear mount angle frame 52R.

As illustrated in FIG. 2, under a state where the guide rail 53 is attached to the rack 50, the microstripline 6-1 is sandwiched between the fixing plate 532 of the guide rail 53 and the front face of the front mount angle frame 51R and is in contact with the guide rail 53. Likewise, at the rear side of the rack 50, the microstripline 6-2 is sandwiched between the fixing plate 532 of the rail 53 and the rear face of the rear mount angle frame 52R and is in contact with the guide rail 53.

Accordingly, the microstripline 6-1 pasted to the front mount angle frame 51R and the microstripline 6-2 pasted to the rear mount angle frame 52R are electrically coupled to each other via the guide rail 53 and come into a state of having electrical continuity.

Besides, the rack 50 is provided with the installing position detector 10, to which the microstripline 6-1 pasted to the front mount angle frame 51R is connected.

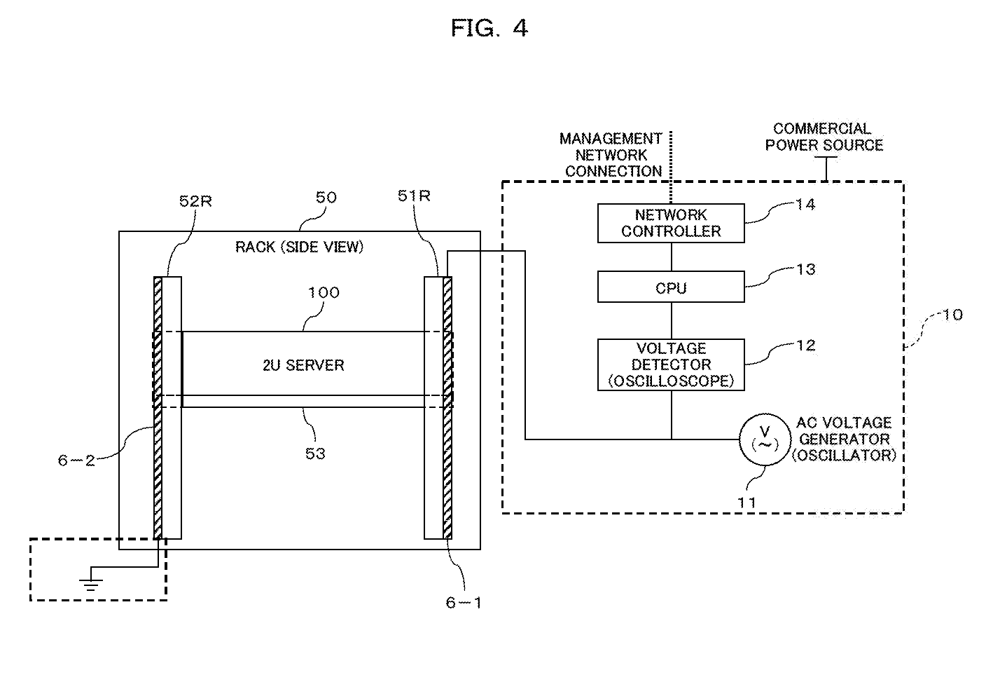

FIG. 4 is a diagram illustrating an example of the hardware configuration of the installing position detector 10 of the computer system 1 of the first embodiment.

As illustrated in FIG. 4, the installing position detector 10 includes an AC voltage generator 11, a voltage detector 12, a Central Processing Unit (CPU) 13, and a network controller 14.

The network controller 14 communicates with the management server 2 and the operation terminal 3 via the network 4. For example, the network controller 14 includes a communication interface such as a LAN card, and carries out data communication via various known protocols such as Hypertext Transfer Protocol (HTTP).

The AC voltage generator (applier) 11 is an oscillator that generates an alternating (AC) voltage. The AC voltage generator 11 is coupled to, for example, the upper end of the microstripline 6-1 and applies an AC voltage to the microstripline 6-1.

The lower end of the microstripline 6-2 pasted to the rear mount angle frame 52R is grounded.

As described above, since the guide rails 53 have conductivity, the microstripline 6-1 pasted to the front mount angle frame 51R and the microstripline 6-2 pasted to the rear mount angle frame 52R have electrically continuity via the guide rail 53.

Under a state where the electronic device 100 is installed in the rack 50, a connection of the voltage generator 11 to the grounding through the microstripline 6-1, the guide rail 53, and the microstripline 6-2 forms a circuit.

In contrast, under a state where the electronic device 100 is not installed in the rack 50, the microstripline 6-1 is not grounded and the circuit is not generated.

The AC voltage generator 11 generates an AC voltage (periodic rectangular wave) having a short rising time and a short falling time of voltage and applies the generated AC voltage to the microstripline 6, so that a circuit considering a distribution multiplier circuit model is formed. In other words, the AC voltage generator 11 generates an AC voltage satisfying a distributed multiplier circuit model.

Here, satisfying a distributed multiplier circuit model corresponds to a case where a voltage rising (Tr) time and a voltage falling time (Tf) are each shorter than the half the time taken to propagate a medium.

Since, in a circuit at a high-frequency domain, an inductance component and a capacitance component of a medium become obvious, it is preferable that the propagation on a line (in this embodiment, the microstripline 6) applied a frequency thereto is modeled for further process. A distributed multiplier circuit model is obtained as a result of modeling circuit elements unlimitedly distributed, not by a limited number of circuit elements being concentrated.

A distributed multiplier circuit model is a well-known technique, so detailed description thereof is omitted here.

The AC voltage generator 11 applies a pulse-shape AC wave to the microstripline 6-1. The AC voltage generator 11 applies a high-frequency voltage to the microstripline 6, regarding the microstripline 6 as a “lead through which electricity flows”.

The voltage detector 12 detects a voltage of the microstripline 6 and specifically detects the waveform of the voltage of the microstripline 6. For example, the voltage detector 12 has a function as an oscilloscope.

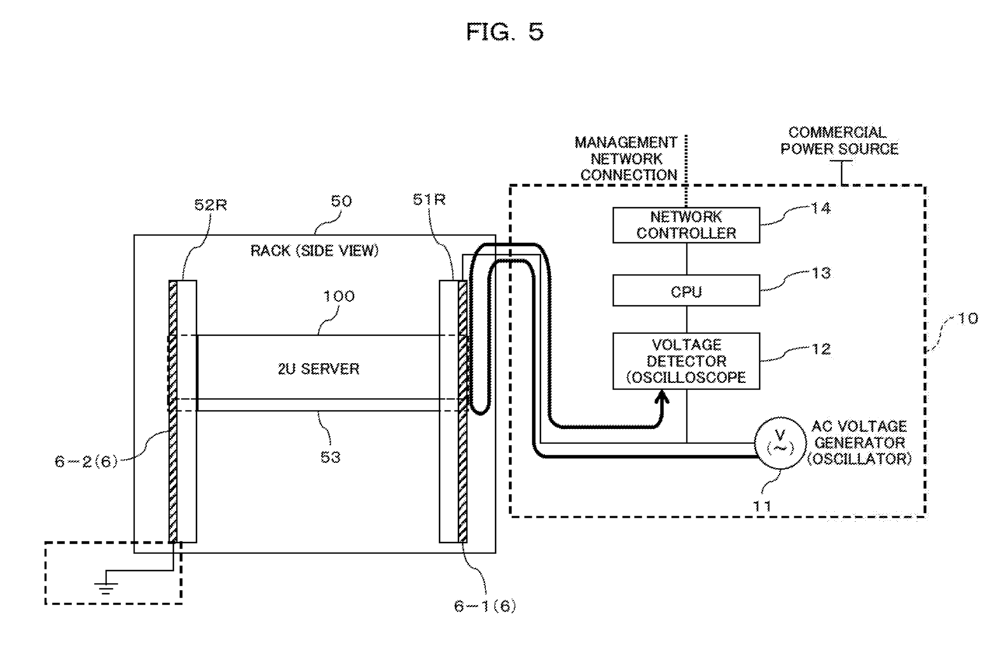

FIG. 5 is a diagram illustrating an alternating wave detected by the voltage detector 12 of the computer system 1 of the first embodiment.

The AC voltage that the AC voltage generator 11 applies from the upper end of the microstripline 6-1 proceeds, being in the form of a wave (alternating wave), downwards in the microstripline 6-1 (going wave) and is reflected at the other end (lower end) of the microstripline 6-1. The reflected alternating wave proceeds in the microstripline 6-1 towards the AC voltage generator 11 (returning wave, reflected wave).

The alternating wave proceeding in the microstripline 6-1 is also reflected at a point (discontinuous point) at which the impedance changes. Accordingly, part of the alternating wave (going wave) proceeding in the microstripline 6-1 is also reflected at a contact between the microstripline 6-1 and the guide rail 53 (fixing plate 532) and then proceeds in the microstripline 6-1 towards the AC voltage generator 11 (returning wave).

In FIG. 5 illustrates an image that the alternating wave that the AC voltage generator 11 applies to the microstripline 6-1 is reflected at the contact face with the guide rail 53 and the reflected alternating wave is detected by the voltage detector 12.

Since the guide rail 53 is made of a conductive material as described above, an alternative wave applied to the microstripline 6-1 flows into the microstripline 6-2 pasted to the rear mount angle frame 52R through the guide rail 53. The alternating wave proceeding in the microstripline 6-2 is also reflected at a point (discontinuous point) at which the impedance changes and then returns to the microstripline 6-1 through the guide rail 53.

Consequently, in the microstripline 6-1, the returning waves having been reflected at the end of the microstripline 6-1 and at points where the impedances are discontinuous in the microstriplines 6-1 and 6-2 are superimposed on the alternating wave (going wave) that the AC voltage generator 11 applies. Hereinafter, the alternative wave obtained by superimposing the returning waves on the going wave is sometimes referred to the superimposed alternating wave.

The voltage detector 12 detects the superimposed alternating wave proceeding through the microstripline 6. In addition, the voltage detector 12 notifies the CPU 13 of information representing the waveform of the measured superimposed alternating wave.

The voltage detector 12 measures (i.e., grasps as a propagating wave) a voltage obtained by time-division on an alternating wave proceeding from the origin (e.g., the upper end) of the microstripline 6 and being reflected at the contact between the guide rail 53 and the microstripline 6 by means of an applied Time-Domain Reflectometry (TDR). In a minute time, a propagating wave needs consideration of a propagation time and the length is calculated from the amount of propagation delay of the propagating wave. From the calculated length, setting position related to an electronic device installed in the rack 50 is detected.

The voltage detector 12 is preferably disposed in the vicinity of the AC voltage generator 11. The waveform that the voltage detector 12 measured in the vicinity of the AC voltage generator 11 is a superimposed alternating wave obtained by, as to be detailed below, superimposing the alternating voltage component (alternating wave) applied by the AC voltage generator 11 on reflected waves generated when the alternating wave reflected in the microstriplines 6.

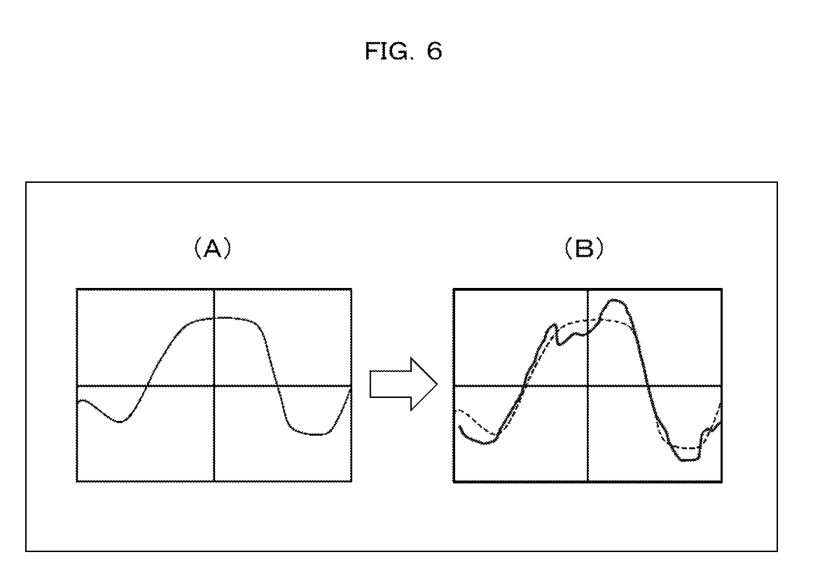

FIG. 6 is a diagram illustrating an alternating wave superimposed in the microstripline 6 of the computer system 1 of the first embodiment. In FIG. 6, the graph (A) represents an example of the waveform of an alternating wave (going wave) generated by the AC voltage generator 11; and graph (B) represents an example of the waveform of a superimposed alternating wave. In the graph (B), a solid line represents a superimposed alternating wave and a broken line represents a going wave.

As illustrated in the drawing, the superimposed alternating wave, which is obtained by superimposing the returning waves on the going wave, has a waveform that distorts the waveform of the going wave. The waveform of the superimposed alternating wave varies with the shape of the going wave and the number of and the type of returning waves contained therein.

Accordingly, the waveform of the superimposed alternating wave is correlated with a position of attaching the guide rail 53 in the rack 50. The waveform of the superimposed alternating wave varies with the position of attaching the guide rail 53 in the rack 50 and/or the number of attached guide rails 53 in the rack 50. Therefore, when the position of attaching the guide rail 53 (i.e., the position of installing an electronic device 100) is the same, the same superimposed alternating wave is detected.

The position of attaching the guide rail 53 in the rack 50 corresponds to the position of installing an electronic device 100 in the rack 50.

The position of the rack 50 along the height direction is represented in a unit of Unit (U). For example, a rack installing position of fifth unit represents that the corresponding electronic device 100 is installed at a position of the fifth unit from the top of the rack 50.

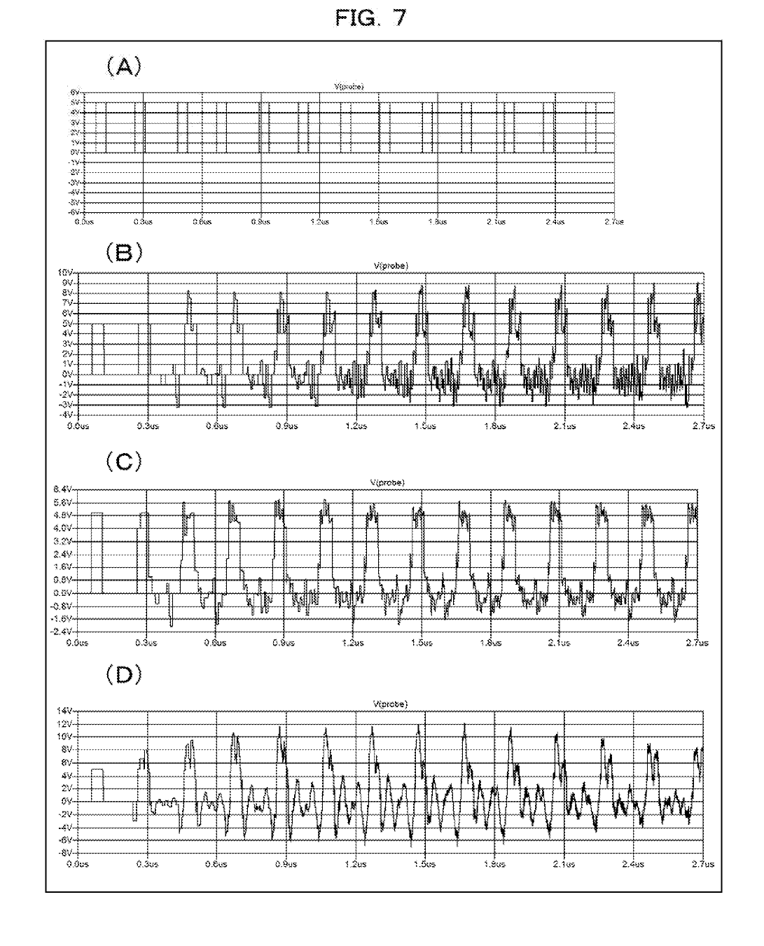

FIG. 7 is a diagram illustrating an example of the waveform of an alternating wave detected by the voltage detector 12 in the computer system 1 of the first embodiment.

In FIG. 7, the graph (A) represents an example of the waveform of an alternating wave (going wave) generated by the AC voltage generator 11.

The graph (B) of FIG. 7 represents an example of a waveform of a superimposed alternating wave measured by the voltage detector 12 under a state where a 1U electronic device 100 is arranged in the position of only the fifth unit from the top of the rack 50.

The graph (C) of FIG. 7 represents an example of a waveform of a superimposed alternating wave measured by the voltage detector 12 under a state where 1U electronic devices 100 are arranged in the positions of the 20th unit, the 10th unit, and the fifth unit from the top of the rack 50.

The graph (D) of FIG. 7 represents an example of a waveform of a superimposed alternating wave measured by the 12 under a state where 1U electronic devices 100 are arranged in the positions of the 20th unit, the 15th unit, the 10th unit, and the fifth unit from the top of the rack 50.

As illustrated in FIG. 7, the waveform of the superimposed alternating wave varies with the position of attaching each guide rail 53 (electronic device 100) in the rack 50 and the number of attached guide rails 53.

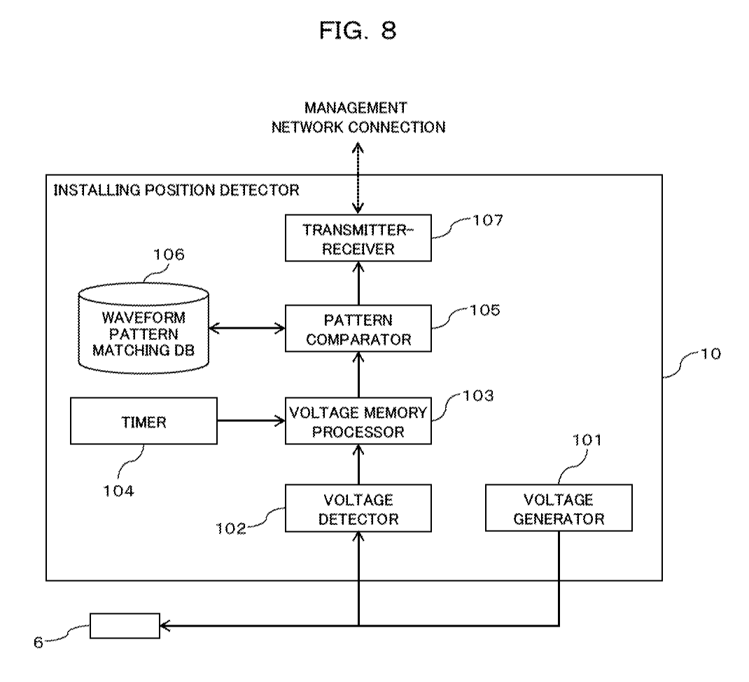

In a waveform pattern matching DB 106 (see FIG. 8), a waveform pattern of a superimposed alternating wave measured by the voltage detector 12 under a state where no electronic device 100 is installed in the rack 50 (i.e., no guide rail 53 is attached), which means the empty rack state, is also registered.

The CPU 13 is a processor that carries out various controls and calculations, and achieves various functions through executing the Operating System (OS) and programs stored in a non-illustrated memory.

FIG. 8 is a diagram illustrating a functional configuration of the installing position detector 10 of the computer system 1 according to the first embodiment.

As illustrated in FIG. 8, the installing position detector 10 has functions of a voltage generator 101, a voltage detector 102, a voltage memory processor 103, a timer 104, a pattern comparator 105, a waveform pattern matching DB 106, and a transmitter-receiver 107.

The transmitter-receiver 107 carries out data communication with the management server 2 and the operation terminal 3, and is achieved by the network controller 14 described above.

The voltage generator 101 generates an alternating voltage (alternating wave) that is to be applied to the microstripline 6 and is achieved by the AC voltage generator 11 described above.

The voltage detector 102 detects an alternating wave (superimposed alternating wave) flowing through the microstripline 6 and measures the waveform of the detected wave, and is achieved by the voltage detector 12 described above.

The CPU 13 achieves the functions as the voltage memory processor 103, the timer 104, and the pattern comparator 105, and functions as the installing position detector.

The program (management program) that achieves the functions of the voltage memory processor 103, the timer 104, and the pattern comparator 105 is provided in the form of being recorded in a tangible and non-transient computer-readable storage medium, such as a flexible disk, a CD (e.g., CD-ROM, CD-R, and CD-RW), a DVD ((DVD-ROM, DVD-RAM, DVD-R, DVD+R, DVD-RW, DVD+RW, HD DVD), a Blue-ray disk, a magnetic disk, an optical disk, and an magneto-optical disk. A computer reads the program from the recording medium using the medium reader and stores the read program in an internal or external storage device for future use. Alternatively, the program may be recorded in a recording device (recording medium) such as a magnetic disk, an optical disk, or a magneto-optical disk, and may be provided from the recording device to the computer via a communication path.

Further alternatively, in achieving the functions of the voltage memory processor 103, the timer 104, and the pattern comparator 105, the program stored in an internal storage device (in this embodiment, the memory included in the installing position detector 10) is executed by the microprocessor (in this example, the CPU 13). At that time, the computer may read the program stored in the recording medium and may execute the program.

The timer 104 counts time. Specifically, the timer 104 counts a predetermined time period, and notifies the voltage memory processor 103 of the count.

The voltage memory processor 103 stores the waveform of a superimposed alternating wave measured by the voltage detector 102 in a non-illustrated storing device such as a memory. The voltage memory processor 103 stores therein a change of voltage per time, and specifically, stores a change (i.e., waveform of an alternating wave) of a voltage measured by the voltage detector 102 during the time period measured by the timer 104 into the storing device.

The waveform pattern matching DB 106 stores therein waveform pattern information 161 that associates a position (installed unit position) of installing each electronic device 100 in the rack 50 with a waveform pattern of a superimposed alternating wave.

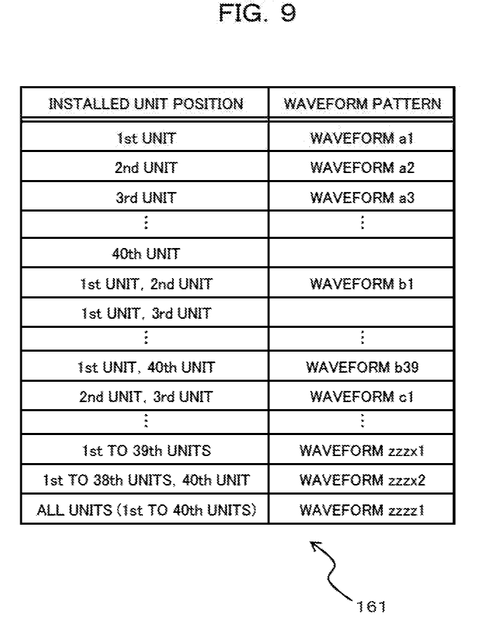

FIG. 9 is a diagram illustrating an example of the waveform pattern information 161 in the computer system 1 of the first embodiment.

As illustrated in FIG. 9, the waveform pattern information 161 is configured by associating a waveform pattern with an installed unit position.

As described above, the waveform of a superimposed alternating wave has a correlation with an installing position of each electronic device 100 in the rack 50 (i.e., the position of attaching each guide rail 53). In this embodiment, it is preferable that waveforms of superimposed alternating waves when one or more electronic devices 100 are installed in the respective slot positions provided for the rack in various arrangements are measured and registered as the waveform pattern information in the waveform pattern matching DB 106 in advance.

The waveform pattern information 161 illustrated in FIG. 9 assumes that 40U electronic devices 100 can be installed in the rack 50 at the maximum. Each waveform pattern in FIG. 9 is represented by a letter string of “waveform xx” (xx is a combination of alphabets and numbers) for the convenience sake, but practically, information representing the waveforms of superimposed alternating waves like the graphs (A)-(D) of FIG. 7 is registered.

Information representing the waveform of a superimposed alternating wave to be registered may be a waveform pattern sampled by the installing position detector 10 or may be feature information that can specify the waveform pattern sampled by the installing position detector 10.

The information representing the waveform of a superimposed alternating wave may be image data of, for example, a waveform of one cycle. The image of a waveform may be replaced with information of an expression and a coordinate representing a form in a numeric value.

The waveform pattern information 161 functions as reference waveform information that associates a state of installing one or more electronic devices 100 in the rack 50 with a waveform pattern of an alternating wave measured under this state.

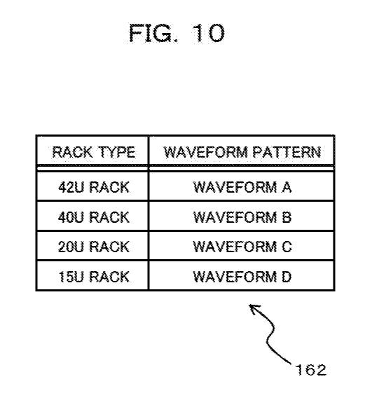

In the waveform pattern matching DB 106, rack specifying pattern information 162 (see FIG. 10) being waveform pattern information to specify the rack 50 is also registered.

FIG. 10 is a diagram illustrating an example of the rack specifying pattern information 162 of the computer system 1 of the first embodiment.

As illustrated in FIG. 10, the rack specifying pattern information 162 is configured by associating “rack type” being information to specify the type of a rack 50 with a waveform pattern.

The waveform pattern in the rack specifying pattern information 162 represents a waveform of a superimposed alternating wave measured (observed) with the voltage detector 12 under a state where no guide rail 53 is attached to a rack 50 of each type and an alternating voltage is applied from the AC voltage generator 11 to the microstripline 6-1.

In the rack specifying pattern information 162 of FIG. 10, waveform patterns are represented by letter strings such as “waveform A”, “waveform B”, “waveform C”, and “waveform D” for the convenience sake, but practically, information representing the waveform of an alternating wave is registered.

The pattern comparator 105 compares a waveform of a superimposed alternating wave stored in the storing device by the voltage memory processor 103 with the waveform pattern information (rack specifying pattern information 162, waveform pattern information 161) stored in the waveform pattern matching DB 106.

For example, the pattern comparator 105 compares a waveform of a superimposed alternating wave stored by the storing device by the voltage memory processor 103 with the rack specifying pattern information 162, and determines the rack type on the basis of the result of the comparison.

For example, when the computer system 1 is stated, the AC voltage generator 11 applies an alternating wave before a guide rail 53 is attached to the rack 50.

When no electronic device 100 is installed in the rack 50, no guide rail 53 is attached, so that the microstripline 6-1 is not connected to the microstripline 6-2. Accordingly, the microstripline 6-1 is not grounded and forms no circuit. When the AC voltage generator 11 applies an alternating voltage to the microstripline 6-1 being in such a state, the alternating wave proceeds to the end (lower end) of the microstripline 6-1 and then reflects at the lower end.

The waveform pattern observed by the voltage detector 12 has a peculiar waveform in which the reflecting wave is superimposed on the applied alternating voltage.

The pattern comparator 105 compares the waveform of a superimposed alternating wave stored in the storing device by the voltage memory processor 103 with the rack specifying pattern information 162 stored in the waveform pattern matching DB 106.

The pattern comparator 105 determines the rack type having a waveform pattern matching the waveform of the superimposed alternating wave as a result of the comparison to be the type of the rack 50.

The pattern comparator 105 compares the waveform of a superimposed alternating wave stored in the storing device by the voltage memory processor 103 with the waveform pattern information 161 stored in the waveform pattern matching DB 106, and on the basis of the result of the comparison, determines the position of installing one or more electronic devices 100 in the rack 50.

Specifically, under a state where one or more electronic devices 100 are installed in the rack 50, the pattern comparator 105 compares the waveform of a superimposed alternating wave stored in the storing device by the voltage memory processor 103 with the waveform pattern information 161 stored in the waveform pattern matching DB 106.

Under a state where an electronic device 100 is installed in the rack 50, the microstripline 6-1 pasted to the front mount angle frame 51R is electrically connected to the microstripline 6-2 pasted to the rear mount angle frame 52R via the guide rail 53 supporting the electronic device 100 being installed. Thereby, the microstripline 6-1 is grounded and a circuit through which the electric current flows is generated.

In the microstripline 6-1, a reflected wave (returning wave) of the alternating wave that depends on the distance from the AC voltage generator 11 to each guide rail 53 and the number of guide rails 53, and the reflected wave is bounced back to the AC voltage generator 11.

The waveform detected by the voltage detector 12 is a superimposed alternating wave generated by superimposing the components of one or more reflected wave of an alternating voltage (alternating wave) applied from the AC voltage generator 11 and reflected in the microstripline 6 on the alternating wave.

The pattern comparator 105 reads the waveform of the superimposed alternating wave stored in the storing device by the voltage memory processor 103 and compares the waveform with the waveform pattern information 161. As a result of the comparison, the pattern comparator 105 determines an installed unit position having a waveform pattern matching the waveform of the superimposed alternating wave to be in a state of installing one or more electronic devices 100 in the rack 50.

The pattern comparator 105 notifies the management server 2 of the determined state of installing an electronic device 100 in the rack 50 via the network controller 14.

The comparison of the waveform of the superimposed wave stored in the storing device by the voltage memory processor 103 with the waveform pattern information 161 or the rack specifying pattern information 162, by the pattern comparator 105, may be accomplished by any known manner and the detailed description thereof is omitted here.

The management server 2 is an information processing apparatus (computer) having a function as a server and manages each rack system 5.

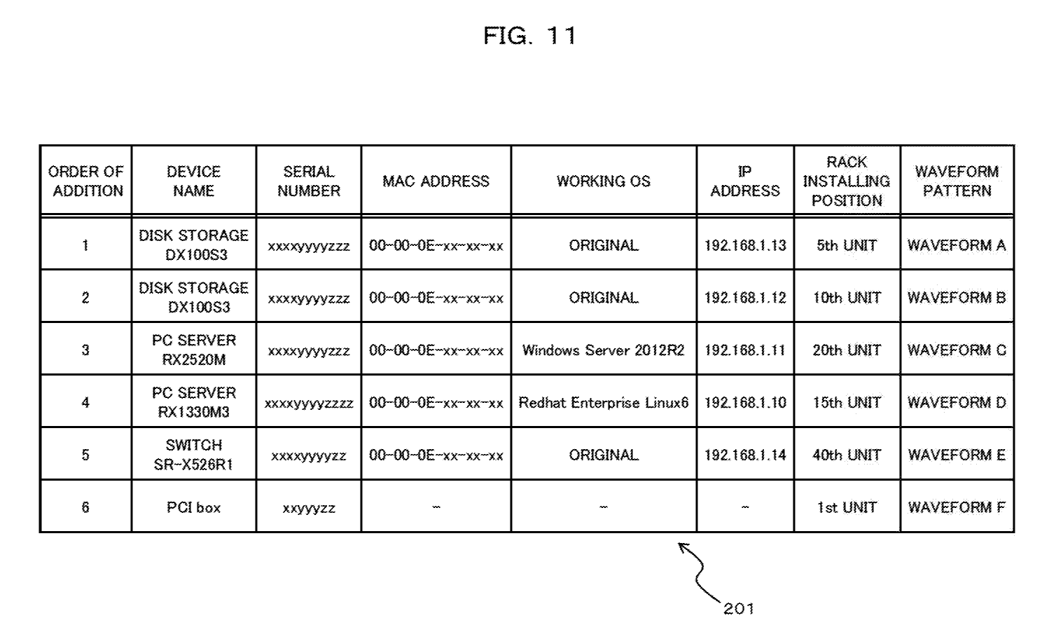

For example, the management server 2 manages the information about the electronic device 100 installed in each rack system 5 through managing the device management table 201 as exemplified in FIG. 11.

FIG. 11 is a diagram illustrating an example of a device management table 201 of the computer system 1 according to the first embodiment.

The device management table 201 illustrated in FIG. 11 associates, for example, an order of addition, a device name, a serial number, a Media Access Control (MAC) address, working Operating System (OS), an Internet Protocol (IP) address, a rack installing position, and a waveform pattern of each electronic device 100 installed in the rack system 5.

Here, the order of addition represents the order of installing (added) the corresponding electronic device 100 in the rack 50. The rack installing position represents the position at which the corresponding electronic device 100 is installed in the rack 50 and specifically, is represented by the height position in the rack 50 being expressed in Unit (U).

The waveform pattern is a waveform pattern of the superimposed alternating wave sampled by the installing position detector 10 that is to be detailed below when the electronic device 100 is installed in the rack 50. The waveform patterns in the device management table 201 as exemplified by FIG. 11 are represented by letter strings of “waveform A” to “waveform F” for the convenience sake, but practically, information representing the waveform patterns like the graphs (A)-(D) of FIG. 7 is stored.

The management server 2 has a function of generating a configuration diagram of the rack system 5. For example, the management server 2 includes a device specification database containing configuration information of the size of each electronic device 100, image data (plan data) representing, for example, the appearance of each electronic device 100, configuration information representing each of various types (rack types) of rack 50, and image data presenting, for example, the appearance of each type of rack 50.

The management server 2 extracts appropriate data and image data from the device specification database and combines the extracted data to generate a configuration diagram of the rack system 5.

The operation terminal 3 is a device through which a person in, for example, charge of managing and operating the computer system 1 (hereinafter called a management operator) makes input/output operation. The operation terminal 3 includes an input device such as a keyboard and a mouse through which the management operator makes an input operation and an output device such as a display through which information is provided to the management operator.

(B) Operation:

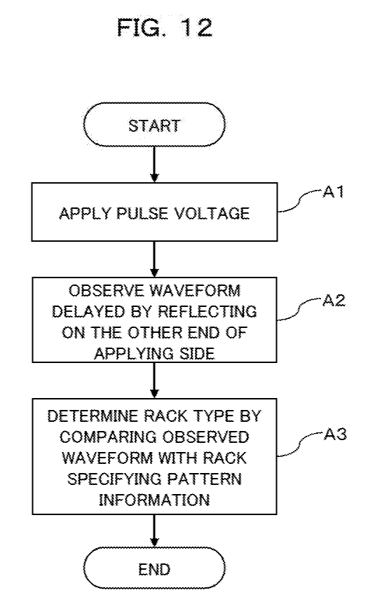

First, description will now be made in relation to a method of determining the type of rack in the computer system 1 of the first embodiment by referring to the flow diagram (steps A1-A3) of FIG. 12.

This process is carried out under a state where no guide rail 53 is attached to the rack 50.

First of all, the AC voltage generator 11 applies a pulse-shape alternating wave to the microstripline 6-1 (step A1).

The alternating wave applied from the one end (upper end) of the microstripline 6-1 by the AC voltage generator 11 proceeds through the microstripline 6-1 (going wave) and is reflected at the other end (lower end) of the microstripline 6-1. The reflected alternating wave (reflected wave) proceeds through the microstripline 6-1 to the AC voltage generator 11 and is superimposed on the going wave to generate a superimposed alternating wave.

The voltage detector 12 measures the superimposed alternating wave. In the superimposed alternating wave, a waveform exhibiting delay generated by the reflected wave is observed (step A2). The waveform of the superimposed alternating wave measured by the voltage detector 102 is stored in a non-illustrated storing device, such as a memory, by the voltage memory processor 103.

The pattern comparator 105 compares the waveform of the superimposed alternating wave stored in the storing device by the voltage memory processor 103 with the rack specifying pattern information 162 stored in the waveform pattern matching DB 106.

Then, the pattern comparator 105 determines a type of rack having a waveform pattern matching the waveform of the superimposed alternating wave as a result of the comparison to be the type of the rack 50 (step A3).

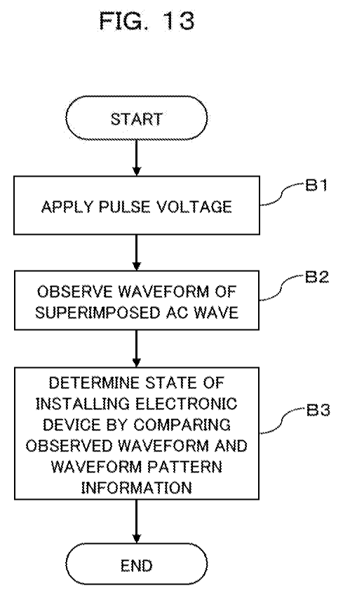

Next, description will now be made in relation to the method of determining an installing state of the electronic device 100 of the computer system 1 of the first embodiment with reference to the flow diagram (step B1-B3) of FIG. 13.

This process is carried out under a state where one or more guide rails 53 are attached to the rack 50.

The AC voltage generator 11 applies a pulse-shape alternating wave to the microstripline 6-1 (step B1).

The alternating wave applied from the one end (upper end) of the microstripline 6-1 by the AC voltage generator 11 proceeds through the microstripline 6-1 (going wave). The alternating wave is reflected at a discontinuous point of impedance in the microstripline 6-1 and at the other end (lower end) of the microstripline 6-1.

The reflected alternating wave (reflected wave) proceeds through the microstripline 6-1 to the AC voltage generator 11 and is superimposed on the going wave to generate a superimposed alternating wave.

The voltage detector 12 measures the superimposed alternating wave. In the superimposed alternating wave, a waveform exhibiting delay caused by the reflected wave is observed (step B2). The waveform of the superimposed alternating wave measured by the voltage detector 102 is stored in a non-illustrated storing device, such as a memory, by the voltage memory processor 103.

The pattern comparator 105 compares waveform of the superimposed alternating wave stored in the storing device by the voltage memory processor 103 with the waveform pattern information 161 stored in the waveform pattern matching DB 106.

Then, the pattern comparator 105 determines an installed unit position associated with a waveform pattern matching the waveform of the superimposed alternating wave as a result of the comparison to be the state of installing the electronic device 100 in the rack 50 (step B3).

The determined installing state of the electronic device 100 is notified to the management server 2.

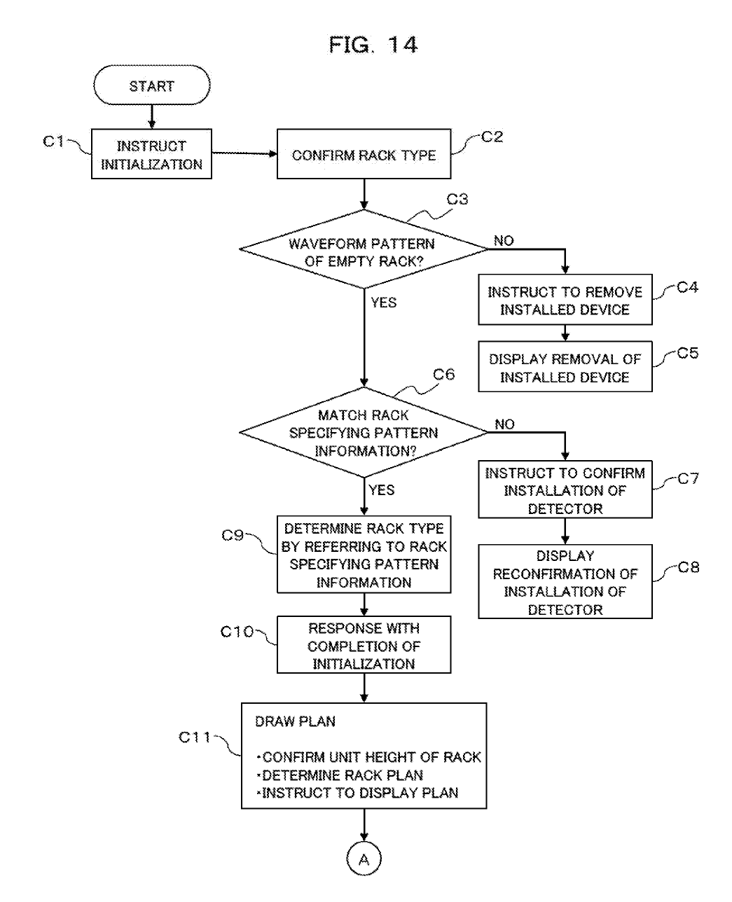

Description will now be made in relation to a process of registering an electronic device 100 in the rack system 5 of the computer system 1 of the first embodiment with reference to flow diagrams (step C1-C36) of FIGS. 14-16.

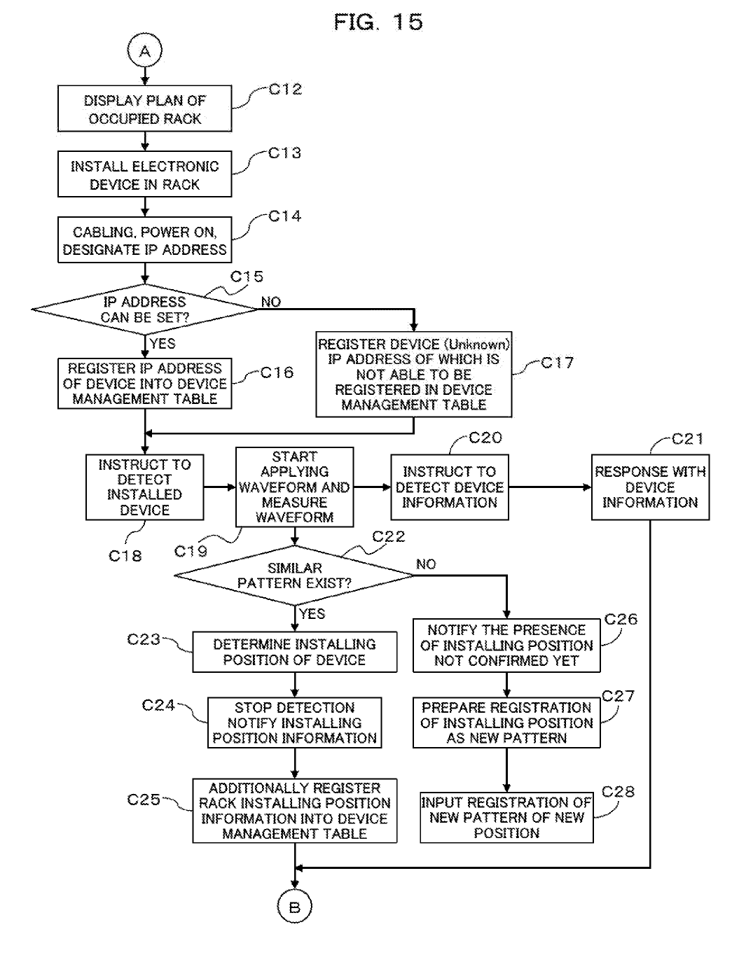

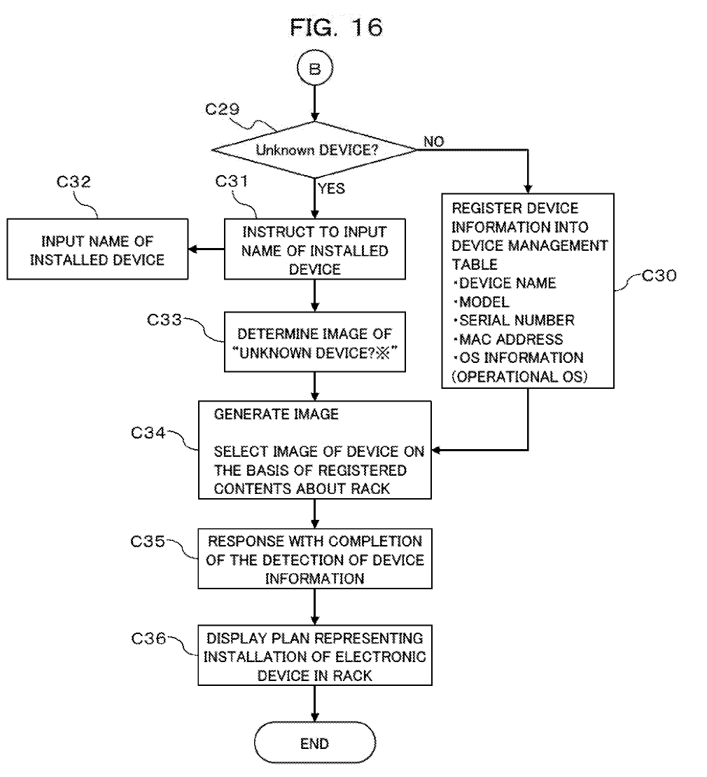

FIG. 14 illustrates the process of steps C1-C11; FIG. 15 illustrates the process of steps C12-C28; and FIG. 16 illustrates the process of steps C29-C36.

This process is carried out when the computer system 1 is installed.

In step C1 of FIG. 14, the management operator (operator) of the computer system 1 inputs an instruction of initialization, using the operation terminal 3.

In step C2 of FIG. 14, the installing position detector 10 determines the type of the rack (see steps A1-A3 of FIG. 12.

In step C3 of FIG. 14, the pattern comparator 105 confirms whether the waveform of the superimposed alternating wave stored in the storing device by the voltage memory processor 103 matches the waveform pattern of the empty rack state among various waveform patterns registered in the waveform pattern matching DB 106.

As a result of the confirmation, if the waveform of the superimposed alternating wave does not match the waveform pattern of the empty rack state (see NO route of step C3), the process moves to step C4 of FIG. 14.

The waveform of the superimposed alternating wave not matching the waveform pattern of the empty rack state means that an electronic device 100 is installed in the rack 50. Therefore, in step C4, the installing position detector 10 instructs the management operator to remove the electronic device 100 installed in the rack 50.

This instruction is displayed on, for example, the display of the operation terminal 3 (step C5 in FIG. 14). It is preferable that, after the electronic device 100 being installed in the rack 50 is removed by the management operator, the process is carried out again from step C1.

As a result of the confirmation in step C3, when the waveform of the superimposed alternating wave matches the waveform pattern of the empty rack state (see YES route of step C3), the process moves step C6 of FIG. 14.

In step C6, the pattern comparator 105 confirms whether the waveform of a superimposed alternating wave matches a waveform pattern of any of the rack types of the rack specifying pattern information 162 stored in the waveform pattern matching DB 106.

As a result of the confirmation, if the waveform of a superimposed alternating wave does not match a waveform pattern of any rack type (NO route of step C6), the process moves to step C7 of FIG. 14.

If the waveform of the superimposed alternating wave under the empty rack state does not match the waveform pattern of any rack type, the voltage detector 12 may have abnormality. Considering the above, the installing position detector 10 instructs the management operator to confirm the state of attaching the voltage detector 12 in step C7.

For example, the installing position detector 10 makes a display that encourages the management operator to reconfirm the state of attaching the voltage detector 12 on the display of the operation terminal 3 (step C8 of FIG. 14). It is preferable that, after the state of attaching the voltage detector 12 is confirmed and corrected if needed by the management operator, the process starts from step C1 again.

As a result of the confirmation in step C6, if the waveform of the superimposed alternating wave match a waveform pattern of any rack type (YES route of step C6), the process moves to step C9 of FIG. 14.

In step C9, the pattern comparator 105 determines the rack type by referring to the rack specifying pattern information 162. In other words, the pattern comparator 105 selects (determines) a rack type having a matched waveform pattern in the rack specifying pattern information 162.

In step C10, the transmitter-receiver 107 of the installing position detector 10 notifies (replies) the completion of the initiation of the rack system 5 to the management server 2. The transmitter-receiver 107 also notifies the determined rack type to the management server 2.

In step C11, the management server 2 draws a plan of the rack 50 based on the rack type received from the rack system 5 (installing position detector 10). For example, the management server 2 extracts (determines) the drawing corresponding to the notified rack type from the appearance views of the respective rack types stored in the management server 2 in advance and transmits the extracted drawing to the operation terminal 3.

In step C12 of FIG. 15, the operation terminal 3 displays the image of the rack 50 transmitted from the management server 2 on the display.

The management operator installs an electronic device 100 into the rack 50 (step C13 of FIG. 15). In addition, the management operator carries out an initial setting process of cabling of the electronic device 100, powering on, and designating an IP address (step C14 of FIG. 15).

The management server 2 confirms, via the network 4, whether an IP address of the electronic device 100 installed in the rack 50 can be set (step C15 of FIG. 15).

If an IP address can be set (see YES route of step C15), the process moves to step C16 of FIG. 15. In step C16, the management server 2 registers the IP address of the electronic device 100 into the device management table 201.

In contrast, if an IP address is not able to be set (see NO route in step C15), the process moves to step C17 of FIG. 15. In step C17, the management server 2 registers the comment that the electronic device 100 is a device the IP address of which is not able to be set (IP unsettable device; unknown device) into the device management table 201.

After that, the management operator inputs, via the operation terminal 3, an instruction of detecting an electronic device 100 installed in the rack 50 (step C18 of FIG. 15).

In the rack system 5, the AC voltage generator 11 of the installing position detector 10 starts application of the alternating wave to the microstripline 6-1. The voltage detector 12 measures the superimposed alternating wave flowing through the microstripline 6-1 (waveform measurement) (step C19 of FIG. 15). The waveform of the superimposed alternating wave measured by the voltage detector 12 is stored into, for example, a non-illustrated memory by the voltage memory processor 103.

The pattern comparator 105 of the installing position detector 10 compares the waveform of the superimposed alternating wave stored in the storing device (e.g., the memory) by the voltage memory processor 103 with the waveform pattern information 161 stored in the waveform pattern matching DB 106. The pattern comparator 105 confirms whether a waveform pattern similar to the waveform of the superimposed alternating wave exists in the waveform pattern information 161 (step C22 of FIG. 15).

As a result of the confirmation, if a waveform pattern similar to the waveform of the superimposed alternating wave exists in the waveform pattern information 161 (YES route in step C22), the process moves to step C23 in FIG. 15. In step C23, the pattern comparator 105 determines the installing position of the electronic device 100 in the rack 50 with reference to the waveform pattern information 161. In other words, the pattern comparator 105 specifies an installing position associated with the similar waveform pattern contained in the waveform pattern information 161.

After that, the installing position detector 10 finishes the detection of the electronic device 100 and the transmitter-receiver 107 notifies the management server 2 of information of the installing position of the electronic device 100 (installing position information) specified in step C23 (step C24 of FIG. 15).

The management server 2 reflects the notified installing position information by additionally registering the information into the device management table 201 (step C25 of FIG. 15).

As a result of the confirmation in step C22, if a waveform pattern similar to the waveform of the superimposed alternating wave does not exist in the waveform pattern information 161 (NO route in step C22), the process moves to step C26 of FIG. 15. In step C26, the transmitter-receiver 107 of the installing position detector 10 notifies the management server 2 of the presence of an installing position not confirmed yet in the rack 50.

Upon receipt of the notification, the management server 2 prepares to register the installing position information in the rack 50, as a new pattern, into the device management table 201 (step C27 of FIG. 15). The management operator inputs (registers) the installing position (new position) of the electronic device 100 in the rack 50, as a new pattern, into the device management table 201 using the operation terminal 3 (step C28 of FIG. 15). After that, the process may move to step C29 of FIG. 16.

In parallel with the confirmation of the presence of a similar pattern in step C22, the management server 2 transmits an instruction of detecting device information to the electronic device 100 (step C20 of FIG. 15). The electronic device 100 replies to the management server 2 with the device information (e.g., device name, serial number, MAC address, working OS, and/or IP address) of the own device (step C21 of FIG. 15).

In step C29 of FIG. 16, the management server 2 confirms whether the electronic device 100 to be registered into the device management table 201 is an unknown device.

As a result of the confirmation, if the electronic device 100 is an unknown device (see YES route in step C29), the process moves to step C31 of FIG. 16.

In step C31, the management server 2 instructs the management operator to input the name of the electronic device 100. This instruction is notified by, for example, displaying the instruction on the display of the operation terminal 3. The management operator inputs the name of the electronic device 100 (installed device) to be registered into the device management table 201, using the operation terminal 3 (step C32 of FIG. 16).

The management server 2 also determines the image of an unknown device (step C33 of FIG. 16). For example, an image of a typical 4U device, which is frequently used as a rack installing device, can be used as the image of an unknown device.

After that, the management server 2 selects images corresponding to the respective electronic devices 100 installed in the rack 50 on the basis of the registered contents related to the rack 50, combines the selected images, and generates the image (rack installing drawing) of the rack 50 being in the state of installing the electronic devices 100 therein (step C34 of FIG. 16).

The management server 2 notifies (responses) the completion of detecting the device information to the management operator (step C35 of FIG. 16). The management operator displays the rack installing drawing generated in step C34 on the operation terminal 3 (step C36 of FIG. 16), and finishes the process.

As a result of the confirmation in step C29, if the electronic device 100 to be registered is not an unknown device (see NO route in step C29), the process moves to step C30.

In step C30, the process registers the device information (e.g., device name, serial number, MAC address, and/or OS information) of the electronic device 100 to be registered into the device management table 201, and then moves to step C34.

If multiple electronic devices 100 are to be installed into the rack 50, the above process is repeated multiple times as many as the electronic devices 100. The process performed for the second and the subsequent times may omit, for example, the process of steps C1-C12.

(C) Effects:

According to the computer system 1 of the first embodiment, the AC voltage generator 11 applies an alternating wave to the microstriplines 6 pasted to the front mount angle frame 51R and the rear mount angle frame 52R of the rack 50.

The installing pattern is specified by measuring a superimposed alternating wave flowing through the microstripline 6 by the voltage detector 12 and comparing waveform of the measured superimposed alternating wave with respective waveform patterns being registered in advance in association with various installing patterns of electronic devices 100 in the rack 50.

Thereby, the installing state of one or more electronic devices 100 in the rack 50, which corresponds to the position of each electronic device 100 in the rack 50, can be easily grasped. Since the installing position detector 10 provided for each rack system 5 specifies the installing state of electronic devices 100 in the own rack 50 of the rack system 5, the installing state (installed unit position) of electronic devices 100 in each rack 50 can be easily grasped even when the computer system 1 includes large number of rack systems 5.

The installing position detector 10 notifies the management server 2 of the grasped installed unit position and this notification makes also the management server 2 possible to easily manage the installing state of electronic devices 100 in the rack 50 of the rack system 5.

Continuously applying the alternating voltage to the microstripline 6 at regular intervals by the AC voltage generator 11 can detect the presence or absence of a guide rail 53 of the rack 50, which corresponds to whether an electronic device 100 is installed in the rack 50, in real time.

The waveform data detected by the installing position detector 10 in real time is transmitted to the management server 2 via the network 4 and the management server 2 manages the waveform data in the device management table 201, so that the device setting information can be obtained automatically.

Since management server 2 manages information about each electronic device 100 installed in the rack 50, using the device management table 201, the information needed for maintenance of the rack 50 can be centralized managed.

The installing position detector 10 determines whether an electronic device 100 is installed in the rack 50 on the basis of the presence and absence of an attached guide rail 53. This makes it possible to determine whether an electronic device 100 is installed in the rack 50 regardless the manufacturer and the specification of each electronic device 100. In addition, even if an article except for an electronic device 100 is installed in the rack 50, the arrangement of the article in the rack 50 can be grasped.

(D) Others:

The technique disclosed herein is not limited to the foregoing embodiment, and various changes and modifications can be suggested without departing from the scope of the embodiment. Each configuration and each process of the first embodiment can be selected, omitted, or combined according to the need.

For example, in the above embodiment, the microstripline 6 pasted to the rear mount angle frame 52R is grounded. However, the foregoing embodiment is not limited to this, and the grounding may be omitted. With this configuration, the voltage detector 12 can obtain the waveform of a superimposed alternating wave in the form of a high-frequency wave from the microstripline 6.

In the foregoing embodiment, the pattern comparator 105 determines the rack type of the rack 50 by referring to the rack specifying pattern information 162, but the embodiment is not limited to this.

Alternatively, the height of the rack 50 (the number of units of the rack 50) may be detected on the basis of the waveform of the alternating wave applied by the AC voltage generator 11 and the waveform of the superimposed alternating wave measured by the voltage detector 12.

Alternatively, the height of the rack 50 may be calculated by dividing half the time period during which the voltage detector 12 detects the alternating wave applied from the AC voltage generator 11 by the propagation delay time. On the basis of the height of the rack 50 calculated as the above, the number of units that can install an electronic device 100 may be determined.

The flow diagram of FIGS. 14-16 assumes a process of installing the electronic device 100 in the rack 50 in the empty rack state when the computer system 1 is installed, but the foregoing embodiment is not limited to this.

The method of managing of the forgoing embodiment can be applied also to a case where another electronic device 100 is additionally installed into an empty slot to the rack 50 in which one or more electronic devices 100 are already installed.

It is assumed that the installing state of one or more electronic devices 100 already installed in the rack 50 is registered in the device management table 201. This means that the device management table 201 registers therein the installing state of one or more electronic devices 100 being installed in the rack 50 having been specified before another electronic device 100 is additionally installed into the rack system 5.

An additional electronic device 100 is newly installed into an empty slot of the rack 50 and the management operator inputs, via the operation terminal 3, an instruction to detect the electronic devices 100 newly installed in the rack 50.

Consequently, the voltage detector 12 measures the waveform of a superimposed alternating wave in the rack 50 into which the additional electronic device 100 has been newly installed, and the voltage memory processor 103 stores the measured waveform into, for example, a non-illustrated memory.

The pattern comparator 105 compares the waveform of the superimposed alternating wave stored in the storing device (e.g., the memory) by the voltage memory processor 103 with the waveform pattern information 161 stored in the waveform pattern matching DB 106 to specify an installed unit position associated with a waveform pattern being similar to the pattern of the measured waveform and being stored in the waveform pattern information 161.

The pattern comparator 105 specifies an installing state of one or more electronic devices 100 in the rack 50 after the additional electronic device 100 has been newly installed into the rack 50.

The pattern comparator 105 compares the installed unit position being specified before the additional electronic device 100 is newly installed and being stored in the device management table 201 with the installed unit position after the additional electronic device 100 is newly installed being specified on the basis of the waveform pattern information 161.

Thereby, the pattern comparator 105 can determine the installing position of the additional electronic device 100 which has been newly installed in the rack 50.

For example, description will now be made in relation to a case where additional electronic device 100 is newly installed into a second unit of the rack 50, in which an electronic device 100 is already installed in the first unit.

In the device management table 201, information representing that an electronic device 100 is already installed in the first unit of the rack 50.

Under this state, the additional electronic device 100 is newly in the second unit, one of the empty slots of the rack 50, and the management operator inputs an instruction, via the operation terminal 3, to detect one or more electronic devices 100 installed in the rack 50. Responsively, the voltage detector 12 measures the waveform of an superimposed alternating wave, and the pattern comparator 105 compares the measured waveform of the superimposed alternating wave with the waveform pattern information 161 stored in the waveform pattern matching DB 106.

The pattern comparator 105 specifies, on the basis of the waveform pattern information 161, that the electronic devices 100 are installed in the first and second units of the rack 50.

Here, the device management table 201 registers therein the specified installing state of installing an electronic device in the rack 50 before the additional electronic device 100 is installed into the second unit, that is a state (installing state) where an electronic device 100 is installed only in the first unit of the rack 50.

The pattern comparator 105 compares the previous installing state (installed unit position=first unit) registered in the device management table 201 with the state (installed unit position=first unit and second unit) of installing the electronic devices 100 in the rack 50 specified by comparing the measured superimposed alternating wave with the waveform pattern information 161.

The pattern comparator 105 determines the difference (installed unit position=second unit) between the previous installing state registered in the device management table 201 and the installing state of installing the electronic devices 100 in the rack 50 specified by comparing the measured superimposed alternating wave with the waveform pattern information 161 as a result of the comparison to be the installing position of the additional electronic device 100 newly installed.

Those ordinary skilled in the art carry out and produce the foregoing embodiment by referring to the above disclosure.

According to the foregoing embodiment, a position of each electronic device installed in the rack 50 can be easily grasped.

All examples and conditional language recited herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present inventions have been described in detail, it should be understood that the various changes, substitutions, and alterations could be made hereto without departing from the spirit and scope of the invention.

What is claimed is:

1. An information processing apparatus comprising:
an applier that applies an alternating voltage to a lead being provided for a frame of a rack that stores one or more electronic devices along a direction of arrangement of the one or more electronic devices, the lead being in contact with a fixing part when the one or more electronic devices are installed;
a measure that measures an alternating wave of the alternating voltage flowing through the lead; and
a specifier that specifies an installing position of an electronic device by referring to reference waveform information with a waveform of the alternating wave measured by the measure, the reference waveform information associating an installing state of installing the one or more electronic devices in the rack with a waveform pattern of the alternating wave measured under the installing state.

2. The information processing apparatus according to claim 1, wherein:
the applier applies the alternating voltage to the lead from a first end of the lead; and
the measure measures a superimposed wave of an alternating wave of the alternating voltage and a reflected wave generated by reflecting the alternating wave in the lead, the alternating wave being generated in the lead.

3. The information processing apparatus according to claim 1, wherein
the lead includes a first lead provided for a first frame of the rack and a second lead provided for a second frame of the rack;
the fixing part has conductivity; and
when the one or more electronic devices are installed in the rack, the first lead is electrically coupled to the second lead by connecting the first frame and the second frame via the fixing part.

4. The information processing apparatus according to claim 1, further comprising the lead.

5. A method of management comprising:
applying an alternating voltage to a lead being provided for a frame of a rack that stores one or more electronic devices along a direction of arrangement of the one or more electronic devices, the lead being in contact with a fixing part when the one or more electronic devices are installed;
measuring an alternating wave of the alternating voltage flowing through the lead; and
specifying an installing position of an electronic device by referring to reference waveform information with a waveform of the alternating wave measured in the measuring, the reference waveform information associating an installing state of installing the one or more electronic devices in the rack with a waveform pattern of the alternating wave measured under the installing state.

6. The method according to claim 5, further comprising:
applying the alternating voltage to the lead from a first end of the lead; and
measuring a superimposed wave of the alternating wave of the alternating voltage and a reflected wave generated by reflecting the alternating wave in the lead, the alternating wave being generated in the lead.

7. The method according to claim 5, wherein
the lead includes a first lead provided for a first frame of the rack and a second lead provided for a second frame of the rack;
the fixing part has conductivity; and
when the one or more electronic devices are installed in the rack, the first lead is electrically coupled to the second lead by connecting the first frame and the second frame via the fixing part.

8. A non-transitory computer-readable recording medium having stored therein a management program that cause a computer to execute a process comprising:
applying an alternating voltage to a lead being provided for a frame of a rack that stores one or more electronic devices along a direction of arrangement of the one or more electronic devices, the lead being in contact with a fixing part when the one or more electronic devices are installed;
measuring an alternating wave of the alternating voltage flowing through the lead; and
specifying an installing position of an electronic device by referring to reference waveform information with a waveform of the alternating wave measured in the measuring, the reference waveform information associating an installing state of installing the one or more electronic devices in the rack with a waveform pattern of the alternating wave measured under the installing state.

9. The non-transitory computer-readable recording medium according to claim 8, wherein the process further comprises:
applying the alternating voltage to the lead from a first end of the lead; and
measuring a superimposed wave of the alternating wave of the alternating voltage and a reflected wave generated by reflecting the alternating wave in the lead, the alternating wave being generated in the lead.

10. A method for specifying an installing position comprising:
applying an alternating voltage to a lead being provided for a frame of a rack that stores plurality of electronic devices including a first electronic device additionally installed in the rack along a direction of arrangement of the plurality of electronic device, the lead being in contact with a fixing part when plurality of electronic devices are installed;
measuring an alternating wave of the alternating voltage flowing through the lead;
specifying an installing state of plurality of electronic devices after the first electronic device is installed by referring to reference waveform information with a waveform of the alternating wave measured in the measuring, the reference waveform information associating an installing state of installing one or more electronic devices in the rack with a waveform pattern of the alternating wave measured under the installing state; and
specifying an installing position of the first electronic device by comparing the state of installing the plurality of electronic devices before the first electronic device is installed and the state of installing the plurality of electronic device after the first electronic device is installed.

11. The method according to claim 10, further comprising:
applying the alternating voltage to the lead from a first end of the lead; and
measuring a superimposed wave of the alternating wave of the alternating voltage and a reflected wave generated by reflecting the alternating wave in the lead, the alternating wave being generated in the lead.

12. The method according to claim 10, wherein
the lead includes a first lead provided for a first frame of the rack and a second lead provided for a second frame of the rack;
the fixing part has conductivity; and
when the one or more electronic devices are installed in the rack, the first lead is electrically coupled to the second lead by connecting the first frame and the second frame via the fixing part.
